(19) United States
(12) Patent Application Publication
(10) Pub. No.: US 2014/0063756 A1
(43) Pub. Date: Mar. 6, 2014

(54) PRINTED CIRCUIT BOARD (PCB), LAMINATING METHOD OF THE PCB AND CHIP ON FLEXIBLE PRINTED CIRCUIT BOARD, AND LCD DEVICE

(71) Applicants: Dongsheng Guo, Shenzhen (CN); Jiang Zhu, Shenzhen (CN)

(72) Inventors: Dongsheng Guo, Shenzhen (CN); Jiang Zhu, Shenzhen (CN)

(73) Assignee: SHENZHEN CHINA STAR OPTOELECTRONICS TECHNOLOGY CO., LTD., Shenzhen, Guangdong 518132 (CN)

(21) Appl. No.: 13/643,297

(22) PCT Filed: Sep. 28, 2012
(86) PCT No.: PCT/CN2012/082256

§ 371 Date: Oct. 25, 2012

(30) Foreign Application Priority Data
Sep. 4, 2012 (CN) 201210323091.3

(51) Int. Cl. H05K 1/14; H05K 3/00

(52) U.S. Cl. CPC H05K 1/142; H05K 3/0058
USPC 361/749; 156/256

(57) ABSTRACT

A laminating method of a chip on flexible printed circuit board (COF) and a printed circuit board assembly (PCBA) includes
arranging an isolation groove on one side or two sides of a laminating area of the PCBA, which is laminated with the COF. The method further includes
laminating the COF onto the PCBA by using a high-temperature laminating bit, so that the PCBA and the COF are connected in the laminating area.

### TECHNICAL FIELD

The present disclosure relates to the field of liquid crystal display (LCD) devices and manufacture, and more particularly to a printed circuit board (PCB), a laminating method of the PCB and a chip on flexible printed, circuit board (COF), and an LCD device.

### BACKGROUND

Current manufacturing process of liquid crystal displays (LCDs) usually relates to interconnection between a chip on flexible printed circuit board (COF) and a printed circuit board (PCB), and interconnection between a display panel electrode and a flexible circuit. In these connections, an anisotropic conducting film is widely employed. The anisotropic conducting film is arranged between components to be connected, and then are pressurized and heated to form a stable and a reliable mechanical electrical connection between the components.

FIG. 1 is a schematic diagram of a typical LCD drive printed circuit board assembly (PCBA) 100. The PCBA 100 is configured with a connecting finger area 101 and a laminating area 102. As shown in FIG. 2, a COF 200 is bonded to the PCBA 100 in the laminating area 102 by a high-temperature laminating bit 300, to connect circuits (connecting fingers) on the PCBA 100 with lines 201 on the COF.

As shown in FIG. 2, the PCB usually thermally expands during heating and pressurizing, and the entire PCBA 100 expands from a center of an area that comes in contact with the high-temperature laminating bit 300 to two sides of the PCBA. The longer the board of the PCBA is, the larger the expansion quantity is. Expansion deformation accumulated onto the two sides of the PCBA causes the laminating area 102 to be significantly offset, and the contact between the laminating area 102 and the COF 200 becomes offset, thereby being unable to effectively connect. As shown in FIG. 3, before laminating, the left, the middle, and the right of the entire COF 200 are aligned with the connecting fingers 103 in the laminating areas 102 of the PCBA 100. As shown in FIG. 4, after laminating, because of the expansion of the PCBA, the entire expansion may be accumulated onto the laminating areas 102, so that the connecting fingers 103 in the laminating areas 102 are significantly misaligned with the lines 201 on the left, the middle and the right of the COF 200, thereby affecting the connectivity, and even causing circuit malfunctions so that the product may not be used normally. At present, one method for solving the problem is reducing design size of the PCBA and controlling temperature of an equipment table. However, difficulties exist when solving the problem through design or equipment control, only after many experiments, reasonable conditions and design values can be obtained, and poor products may be produced when control is not proper. Thus, the problem needs to be solved urgently.

### SUMMARY

In view of the above-described problems, the aim of the present disclosure is to provide a printed circuit board (PCB) which is well connected between a printed circuit board assembly (PCBA) and a chip on flexible printed circuit board (COF), a laminating method of the PCB and the COF, and a liquid crystal display (LCD) device.

The aim of the present disclosure is achieved by the following technical scheme.

A laminating method of the COF and the PCBA comprises the following steps:

A: arranging an isolation groove on one side or two sides of a laminating area of the PCBA, which is laminated together with the COF in the laminating area; and

B: laminating the COF onto the PCBA by using a high-temperature laminating bit, so that the PCBA and the COF are connected in the laminating area.

In one example, in the step A, one or more isolation grooves are arranged between two adjacent laminating areas. By arranging one or more isolation grooves between the two laminating areas, expansion of the PCBA between the two laminating areas is reduced.

In one example, only one isolation groove is arranged between the two adjacent laminating areas, and the isolation groove starts from a boundary of the first laminating area and ends at a boundary of the second laminating area. Only one isolation groove is arranged and the isolation groove spans from the first laminating area to the second laminating area, so that the laminating bit only comes in contact with the laminating areas. Thus, expansion of the PCBA is reduced to a minimum.

An LCD device comprises a drive PCBA and a COF, wherein an isolation groove is arranged on one side or two sides of a laminating area of the drive PCBA, which is laminated together with the COF in the laminating area.

In one example, one or more isolation grooves are arranged between the two adjacent laminating areas. By arranging one or more isolation grooves between the two laminating areas, expansion of the PCBA between the two laminating areas is reduced.

In one example, only one isolation groove is arranged between the two adjacent laminating areas, and the isolation groove starts from is boundary of the first laminating area and ends at a boundary of the second laminating area. Only one isolation groove is arranged and the isolation groove spans from the first laminating area to the second laminating area, so that the laminating bit only comes in contact with the laminating areas. Thus, the expansion of the PCBA is reduced to a minimum.

A PCB connecting with the COF comprises a laminating area where the PCB is laminated together with the COF, and wherein one side or two sides of the laminating area is configured with an isolation groove.

In one example, two sides of each laminating area of the PCB are respectively configured with the isolation groove, and each isolation groove ends at a boundary of the adjacent laminating areas. The isolation grooves are used to prevent expansion of the PCB from being accumulated onto the laminating areas.

In one example, one or more isolation grooves are arranged between two adjacent laminating areas. By arranging one or more isolation grooves between two adjacent laminating areas, expansion of the PCB between two laminating areas is reduced.

In one example, only one isolation groove is arranged between the two adjacent laminating areas, and the isolation groove starts from a boundary of the first laminating area and ends at a boundary of the second laminating area. Only one isolation groove is arranged and the isolation groove spans from the first laminating area to the second laminating area, so that the laminating bit only comes in contact with the laminating areas. Thus, expansion of the PCB is reduced to a minimum.

In the present disclosure, the isolation groove is arranged on one side or two sides of the laminating area where the PCBA and the COF are laminated together, which enables one side or two sides of the laminating area of the PCBA to be not affected by the high temperature of the laminating bit, and large displacement of the connecting figures of the laminating area caused by accumulating the deformation of the PCB at the two sides onto the PCB of the laminating area is reduced. Namely, because the PCB of one side or two sides of the laminating area is removed, the accumulated deformation of the PCB of the laminating area is reduced, so that the connecting figures of the laminating area may not be significantly displaced, and the accuracy of connection between the lead wires on the COF and the connecting fingers on the PCBA is increased.

### BRIEF DESCRIPTION OF FIGURES

FIG. 1 is a simplified structure diagram of a drive printed circuit board assembly (PCBA) of a typical liquid crystal display (LCD) device;

FIG. 2 is a connection diagram of a drive PCBA and a chip on flexible printed circuit board (COF) of a typical LCD device;

FIG. 3 is an alignment diagram of as drive PCBA and as COF before connection of a typical LCD device;

FIG. 4 is an alignment diagram of a drive PCBA and as COF after connection of a typical LCD device;

FIG. 5 is a simplified structure diagram of a drive PCBA of an LCD device of a first example of the present disclosure;

FIG. 6 is a connection diagram of a drive PCBA and a COF of an LCD device of a first example of the present disclosure;

FIG. 7 is an alignment diagram of a drive PCBA and a COF before connection of an LCD device of a first example of the present disclosure;

FIG. 8 is an alignment diagram of a drive PCBA and a COF after connection of an LCD device of a first example of the present disclosure;

FIG. 9 is a connection diagram of a drive PCBA and a COF of an LCD device of a first example of the present disclosure;

FIG. 10 is a simplified structure diagram of a drive PCBA of an LCD device of a second example of the present disclosure; and

FIG. 11 is a connection diagram of a drive PCBA and a COF of an LCD device of a second example of the present disclosure.

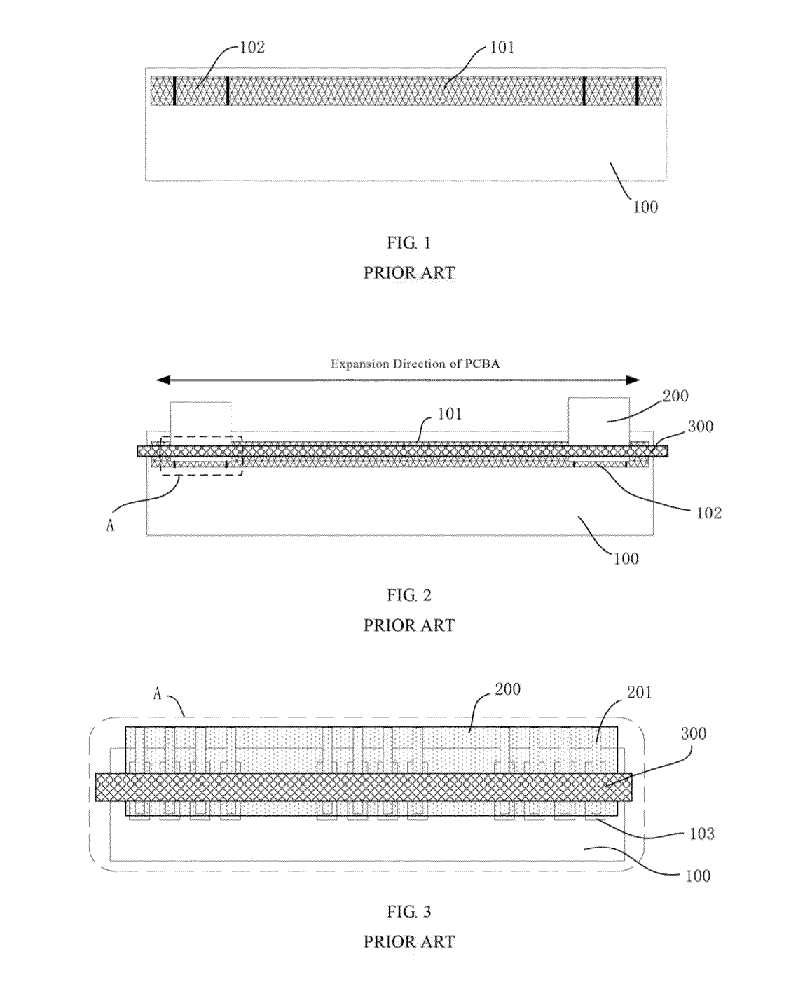

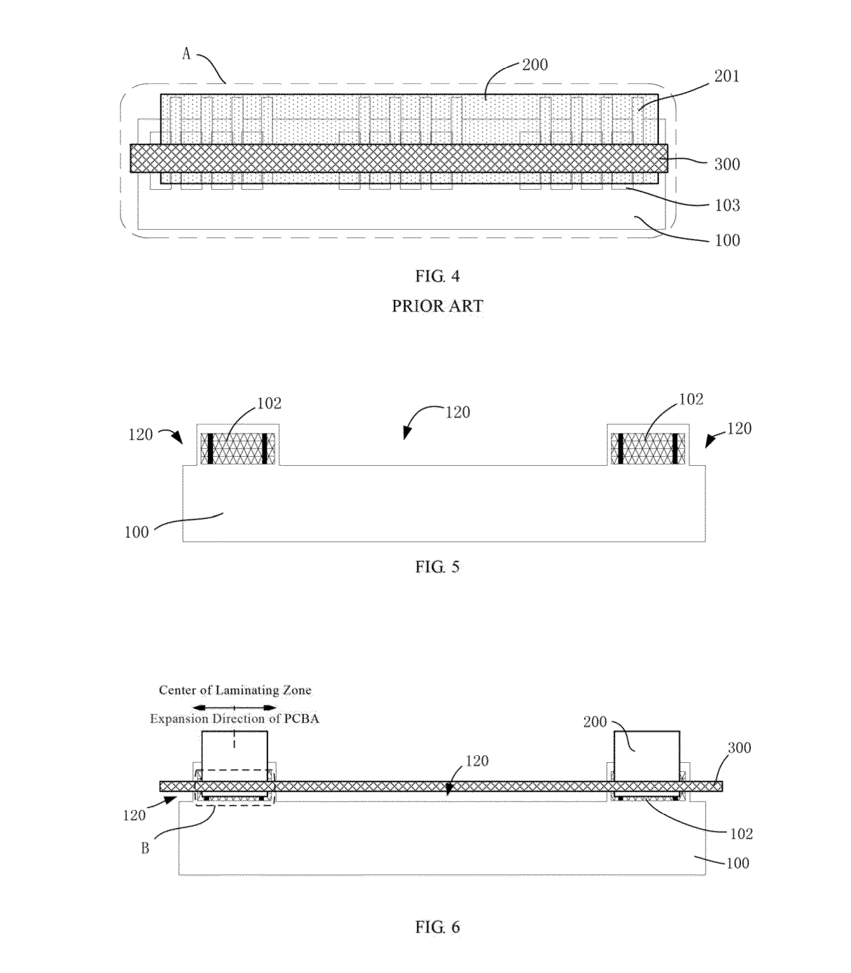

Legends: 100. printed circuit board assembly (PCBA); 101. connecting finger area; 102, laminating area; 103. connecting finger; 120, isolation groove; 200. chip on flexible printed circuit board (COF); 201. line; 300. laminating bit.

### DETAILED DESCRIPTION

The present disclosure will be further described in accordance with the figures and preferred examples.

The present disclosure will he further described by using a method of connecting a drive printed circuit board assembly (PCBA) and a chip on flexible printed circuit board (COF) of a liquid crystal display (LCD) device as an example.

### Example 1

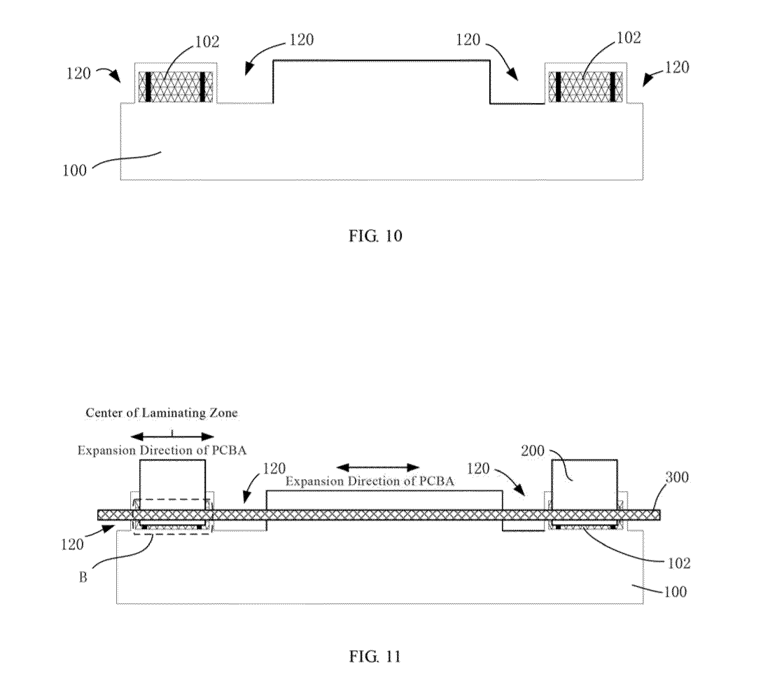

As shown in FIGS. 5-9, one method of connecting the printed circuit board assembly (PCBA) 100 and the chip on flexible printed circuit board (COF) 200 comprises the following steps:

A: as shown in FIG. 5, arranging an isolation groove 120 on one side or two sides of a laminating area 102 of the PCBA 100, which is laminated together with the COF 200 in the laminating area; and

B: as shown in FIG. 6, laminating the COF 200 onto the PCBA 100 by using a high-temperature laminating bit 300, so that the PCBA 100 and the COF 200 are connected in the laminating area 102.

In the example, the drive PCBA 100 of the LCD device is configured with two laminating areas 102, only one isolation groove 120 is arranged between two adjacent laminating areas, and the isolation groove starts from a boundary of the first laminating area and ends at a boundary of the second laminating area. Thus, contact area between the PCBA 100 and the laminating bit 300 is reduced to a minimum, and only the laminating areas 102 are in contact with the laminating bit 300. Therefore, thermal deformation only occurs in the laminating areas 102. In addition, as shown in FIG. 5, the other side opposite to the isolation groove between the two laminating areas 102 is configured with the isolation groove 120. In the example, because the two laminating areas 102 are positioned at an edge of the board body of the PCBA 100, the PCB material of the edge of the PCBA is directly removed when arranging the isolation groove 120 at the edge.

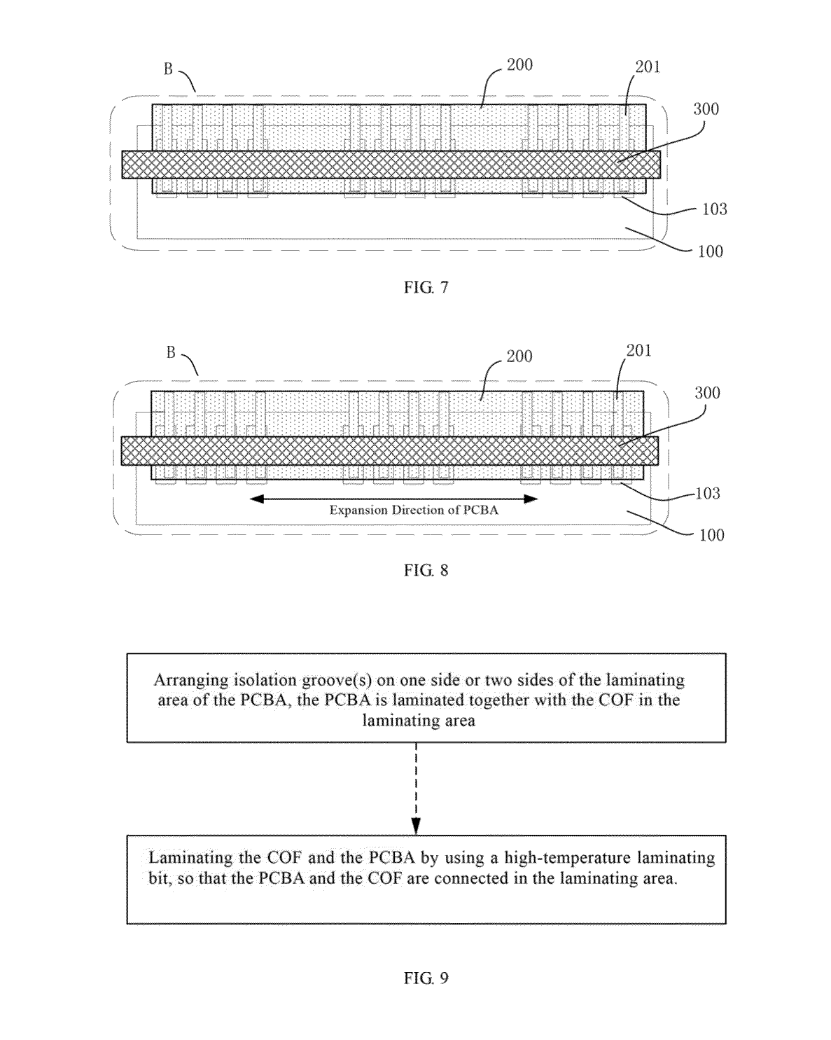

As shown in FIG. 7, the connecting lingers 103 on the PCBA 100 are aligned with lines 201 on the COF 200 between the PCBA 100 and the COF 200 before laminating. As shown in FIG. 8, after the laminating area 102 is heated and pressurized by the laminating bit 300, the PCB material of the laminating areas 102 deforms and expands from the center to the two sides. However, because the laminating area 102 is small, the accumulated expansion deformation is small, and the displacement of the connecting fingers 103 is small. The lines 201 on the COF 200 can still be well connected with the connecting fingers 103, and the displacement of the connecting fingers 103 near the center of the laminating area 102 is at a minimum. Such small deformation ensures the accuracy of connection between the COF 200 and the PCBA 100, and ensures production yield of LCD devices.

In the example, the isolation groove is arranged on the two sides of the laminating area 102 where the PCBA and the COF are laminated together, which enables the two sides of the laminating area 102 of the PCBA 100 to be not affected by the high temperature of the laminating bit 300, and large displacement of the connecting FIGS. 103 of the laminating area 102 caused by accumulation of the deformation of the PCB material at the two sides of the laminating area 102 onto the PCB material of the laminating area 102 is avoided. Namely, because the PCB material on the two sides of the laminating area 102 is removed, the PCB material of the laminating area 102 is not affected by the accumulated deformation, so that the connecting figures of the laminating area 102 may not be significantly displaced, and the accuracy of connection between the lines 201 on the COF 200 and the connecting fingers 103 on the PCBA 100 is increased.

### Example 2

As shown in FIG. 10, the example is different from the first example in that: two isolation grooves 120 are arranged between the two laminating areas 102, and the PCB material between the two isolation grooves 120 is still reserved. Thus, wiring area of the PCB can be increased, and the deformation of the PCB material reserved between the two isolation grooves 120 during expansion can be prevented from accumulating onto the laminating areas 102. Both the two isolation grooves 120 between the two laminating areas 102 are arranged on one side of the laminating area 102, and the other side of the laminating area 102 is configured with the isolation groove 120, namely the two sides of the laminating area 102 are respectively configured with the isolation groove 120, and each isolation groove 120 ends at the boundary of the adjacent laminating area 102.

As shown in FIG. 11, although the reserved part expands and deforms to the two sides when heated by the laminating bit 300, expansion deformation may not be accumulated onto the laminating area 102 because of the isolation grooves 120, or expansion deformation may have a small effect on the laminating area 102. Thus, expansion deformation of the laminating area 102 may be small, and the connecting fingers may not be significantly displaced.

Optionally, for the example, more than two isolation grooves 120 can be arranged as well, and expansion deformation can be ensured not to affect the laminating areas when ensuring the area of the PCB material.

In accordance with the aforementioned example, the present disclosure further provides a printed circuit board (PCB) with the aforementioned structure. The PCB with the structure can be specially used to connect with the COF. Therefore, the PCB can be produced in mass as required.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements.

We claim:

1. A laminating method of a chip on flexible printed circuit board (COF) and a printed circuit board assembly (PCBA), comprising:
A: arranging an isolation groove on one side or two sides of a laminating area of the PCBA, which is laminated together with the COF in the laminating area; and
B: laminating the COF onto the PCBA by using a laminating bit, so that the PCBA and the COF are connected in the laminating area.

2. The laminating method of the chip on flexible printed circuit board (COF) and the printed circuit board assembly (PCBA) of claim 1, wherein in the step A, the PCBA comprises a plurality of laminating areas which are positioned side-by-side, and one or more isolation grooves are arranged between two adjacent laminating areas.

3. The laminating method of the chip on flexible printed circuit board (COF) and the printed circuit board assembly (PCBA) of claim 2, wherein only one isolation groove is arranged between the two adjacent laminating areas, and the isolation groove starts from a boundary of the first laminating area and ends at a boundary of the second laminating area.

4. A liquid crystal display (LCD) device, comprising:
a drive printed circuit board assembly (PCBA); and
a chip on flexible printed circuit board (COF);
wherein an isolation groove is arranged on one or two sides of a laminating area of the drive PCBA, which is laminated together with the COF in the laminating area.

5. The liquid crystal display (LCD) device of claim 4, wherein the PCBA comprises a plurality of laminating areas which are positioned side-by-side, and one or more isolation grooves are arranged between two adjacent laminating areas.

6. The liquid crystal display (LCD) device of claim 5, wherein only one isolation groove is arranged between the two adjacent laminating areas, and the isolation groove starts from a boundary of the first laminating area and ends at a boundary of the second laminating area.

7. A printed circuit board (PCB) connecting with a chip on flexible printed circuit board (COF), comprising:
a laminating area where the PCB is laminated together with the COF, and wherein one side or two sides of the laminating area is configured with an isolation groove.

8. The printed circuit board (PCB) connecting with the chip on flexible printed circuit board (COF) of claim 7, wherein two sides of each laminating area of the PCB are respectively configured with the isolation groove, and each isolation groove ends at a boundary of an adjacent laminating area.

9. The printed circuit board (PCB) connecting with the chip on flexible printed circuit board (COF) of claim 7, wherein the PCBA comprises a plurality of laminating areas which are positioned side-by-side, and one or more isolation grooves are arranged between two adjacent laminating areas.

10. The printed circuit board (PCB) connecting with the chip on flexible printed circuit board (COF) of claim 9, wherein only one isolation groove is arranged between the two adjacent laminating areas, and the isolation groove starts from a boundary of the first laminating area and ends at a boundary of the second laminating area.
